(19) United States
(12) Patent Application Publication
(10) Pub. No.: US 2024/0276820 A1
(43) Pub. Date: Aug. 15, 2024

(54) DISPLAY PANEL AND ELECTRONIC DEVICE

(71) Applicants: WUHAN TIANMA MICROELECTRONICS CO., LTD., Wuhan (CN); WUHAN TIANMA MICROELECTRONICS CO., LTD. SHANGHAI BRANCH, Shanghai (CN)

(72) Inventors: Zhuan GAO, Shanghai (CN); Peng ZHANG, Shanghai (CN); Qibing WEI, Shanghai (CN)

(73) Assignees: WUHAN TIANMA MICROELECTRONICS CO., LTD., Wuhan (CN); WUHAN TIANMA MICROELECTRONICS CO., LTD. SHANGHAI BRANCH, Shanghai (CN)

(21) Appl. No.: 18/637,473

(22) Filed: Apr. 17, 2024

(30) Foreign Application Priority Data
May 25, 2023 (CN) 202310622866.5

(51) Int. Cl. H10K 59/131

(52) U.S. Cl. CPC H10K 59/1315

(57) ABSTRACT

A display panel and an electronic device are provided. The display panel includes: a substrate, a first power signal line and a first connection line. The substrate includes a display region and a non-display region surrounding the display region, where the display region includes a first display sub-region and a second display sub-region, the non-display region includes a first non-display sub-region and a second non-display sub-region, the first non-display sub-region includes a binding region, and the binding region is opposite to the first display sub-region The first power signal line is located in the second non-display sub-region. The first connection line is electrically connected to a part of the first power signal line, extends to the binding region, and is at least partially located in the first display sub-region. A width of the first connection line is smaller than a width of the first power signal line.

This application claims priority to Chinese Patent Application No. 202310622866.5, filed with the China National Intellectual Property Administration on May 25, 2023 and entitled “DISPLAY PANEL AND ELECTRONIC DEVICE”, which is incorporated herein by reference in its entirety.

### FIELD

The present disclosure relate to the field of electronic devices, and specifically, to a display panel and an electronic device.

### BACKGROUND

With the continuous advancement of science and technology, more and more electronic devices with display functions are widely used in people's daily life and work, which bring great convenience and have become important tools for people nowadays.

A main component of an electronic device to realize the display function is a display panel. The display panel includes a display region and a non-display region surrounding the display region. In an existing display panel, since binding regions, various signal lines and circuit structures are provided in the non-display region, the width of the non-display region is relatively large, which is disadvantageous for a narrow frame design.

### SUMMARY

The present disclosure provides a display panel and an electronic device.

One embodiment of the present disclosure provides a display panel, including a substrate, a first power signal line and a first connection line.

The substrate includes a display region and a non-display region surrounding the display region, where the display region includes a first display sub-region and a second display sub-region arranged in sequence in a first direction; the non-display region includes a first non-display sub-region arranged along a periphery of the first display sub-region and a second non-display sub-region arranged along a periphery of the second display sub-region; the first non-display sub-region includes a binding region, and the binding region is opposite to the first display sub-region in the first direction.

The first power signal line is located in the second non-display sub-region.

The first connection line is electrically connected to a part of the first power signal line and extends to the binding region, and at least a part of the first connection line is located in the first display sub-region, a width of the first connection line is smaller than a width of the first power signal line.

It can be known from the above description that, in the display panel provided by the present disclosure, the first power signal is transmitted through the first power signal line and the first connection line. At least a part of the first connection line being set in the first display sub-region can reduce the layout space of the wire for transmitting the first power signal in the first non-display sub-region, to reduce the width of the first non-display sub-region and facilitating the narrow frame design. The width of the first connection line being set to be smaller than the width of the first power signal line can reduce the layout space of the first connection line in the first display sub-region.

The present disclosure also provides an electronic device including the above-mentioned display panel.

It can be known from the above description that the electronic device provided by the present disclosure includes the above display panel, which can at least reduce the width of the first non-display sub-region, to facilitate the narrow frame design.

### BRIEF DESCRIPTION OF DRAWINGS

In order to more clearly illustrate the embodiments of the present disclosure or related technologies, the following briefly introduces the accompanying drawings to be used in the description of the embodiments or related technologies. The accompanying drawings in the following description are only for the embodiments of the present disclosure, other drawings can be obtained according to the provided drawings.

The structures, proportions, sizes, etc. shown in the drawings of this specification are only used to cooperate with the content disclosed in the specification, for those who are familiar with this technology to understand and read, and are not used to limit the embodiments, so without substantive significance, any modification of the structure, change of the proportional relationship or adjustment of the size shall still fall within the scope covered by the technology content disclosed in the application without affecting the effect and purpose of the application.

FIG. 1 is a schematic structural diagram of a display panel.

FIG. 2 is a schematic structural diagram of a display panel according to an embodiment of the present disclosure.

FIG. 3 is a sectional view of a display panel according to an embodiment of the present disclosure.

FIG. 4 is a top view of a transition layer according to an embodiment of the present disclosure.

FIG. 5 is a top view of a transition layer provided by another embodiment of the present disclosure.

FIG. 6 is a sectional view of another display panel according to an embodiment of the present disclosure.

FIG. 7 is a top view of a transition layer in the display panel shown in FIG. 6.

FIG. 8 is a partial enlarged top view of a display panel according to an embodiment of the present disclosure.

FIG. 9 is a sectional view of FIG. 8 in the M-M′ direction.

FIG. 10 is a partial enlarged top view of another display panel according to an embodiment of the present disclosure.

FIG. 11 is a sectional view of FIG. 10 in the M-M′ direction.

FIG. 12 is a partial enlarged top view of another display panel according to an embodiment of the present disclosure.

FIG. 13 is a sectional view of another display panel according to an embodiment of the present disclosure.

FIG. 14 is a partial enlarged top view of another display panel according to an embodiment of the present disclosure.

FIG. 15 is a top view of a cathode layer in a non-display region according to an embodiment of the present disclosure.

FIG. 16 is a sectional view of another display panel according to an embodiment of the present disclosure.

FIG. 17 is a schematic structural diagram of another display panel according to an embodiment of the present disclosure.

FIG. 18 is a schematic structural diagram of another display panel according to an embodiment of the present disclosure.

FIG. 19 is a schematic structural diagram of an electrostatic discharge circuit according to an embodiment of the present disclosure.

FIG. 20 is a schematic structural diagram of another display panel according to an embodiment of the present disclosure.

FIG. 21 is a sectional view of the display panel shown in FIG. 20 in the A-A direction.

FIG. 22 is a sectional view of a display panel in a direction perpendicular to the extending direction of a retaining wall according to an embodiment of the present disclosure.

FIG. 23 is a schematic structural diagram of another display panel according to an embodiment of the present disclosure.

FIG. 24 is a partial enlarged view of a display panel according to an embodiment of the present disclosure.

FIG. 25 is a partial enlarged view of another display panel according to an embodiment of the present disclosure.

FIG. 26 is a schematic structural diagram of an electronic device according to an embodiment of the present disclosure.

### DESCRIPTION OF EMBODIMENTS

The following describes the embodiments of the present disclosure with reference to the accompanying drawings of embodiments. It is clear that the described embodiments are merely a part rather than all of embodiments.

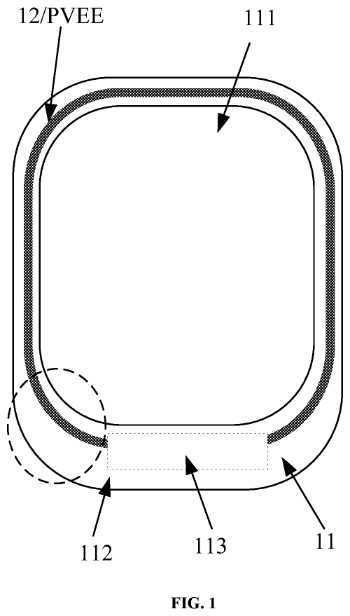

FIG. 1 is a schematic structural view of a display panel. The display panel includes a substrate 11 having a display region 111 and a non-display region 112 surrounding the display region 111. The non-display region 112 on one side of the display region 111 includes a binding region 113 for arranging a control chip. The non-display region 112 includes a wire 12 for transmitting a first power signal PVEE. The wire 12 is located in the non-display region 112, surrounding the display region 111. Two ends of the wire 12 are connected to pads in the binding region 113, to provide the first power signal PVEE through the control chip connected to the binding region.

In the embodiment of the present disclosure, the first power signal PVEE is generally a negative voltage power signal. The wire 12 surrounding the display region 111 can not only provide the first power signal PVEE for the sub-pixels in the display region 111, but also provide electrostatic protection for metal structures in an area surrounded by the wire 12, preventing the metal structures from being damaged by electrostatic breakdown.

As shown in FIG. 1, the binding region 113 is set in the non-display region 112 on a lower side of the display region 111 as an example for illustration. Generally, the non-display region 112 on both sides of the display panel further includes a driving circuit (not shown in FIG. 1) located between the wire 12 and the display region 111. Therefore, in a lower R corner region (a region indicated by a dotted ellipse in FIG. 1), it is necessary to arrange not only the wire 12 to connect a part of the binding region 113, but also other signal lines, such as signal lines used to connect the driving circuit to provide input signals for the driving circuit, and fan-out lines used to connect pixel circuits at an edge of the display region.

Since signal lines need to be arranged in the above-mentioned R corner region, the width of the R corner region is relatively large, resulting in a large width of a frame at the lower end of the display panel, which is disadvantages for a narrow frame design of the display panel.

In view of this, the present disclosure provides a display panel and an electronic device, in which a first power signal is transmitted through a first power signal line and a first connection line. By arranging at least a part of the first connection line in the first display sub-region, the space occupied by the wire for transmitting the first power signal in the first non-display sub-region can be reduced, to reduce the width of the first non-display sub-region and facilitating the narrow frame design. By setting the width of the first connection line to be smaller than the width of the first power signal line, the space occupied by the first connection line in the first display sub-region can be reduced.

In order to make the embodiments of the present disclosure understandable, the embodiments are further described in detail below in conjunction with the accompanying drawings.

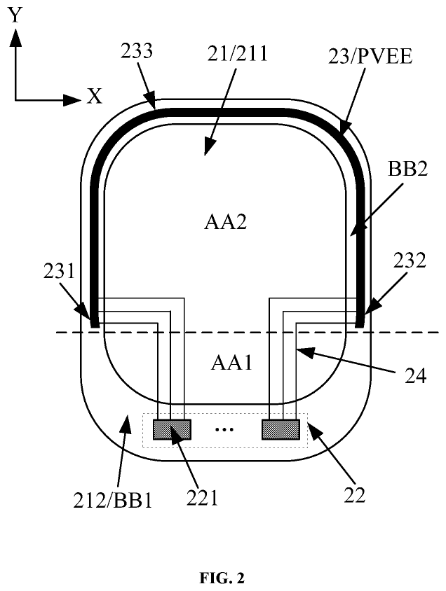

FIG. 2 is a schematic structural diagram of a display panel according to an embodiment of the present disclosure. The displayed display panel includes a substrate 21, a first power signal line 23, and a first connection line 24.

The substrate 21 includes a display region 211 and a non-display region 212 surrounding the display region 211. The display region 211 includes a first display sub-region AA1 and a second display sub-region AA2 arranged sequentially in a first direction Y. The non-display region 212 includes a first non-display sub-region BB1 arranged along a periphery of the first display sub-region AA1 and a second non-display sub-region BB2 arranged along a periphery of the second display sub-region AA2. The first non-display sub-region BB1 includes a binding region 22, and the binding region 22 is opposite to the first display sub-region AA1 in the first direction Y.

The first power signal line 23 is located in the second non-display sub-region BB2.

The first connection line 24 is electrically connected to a part of the first power signal line 23, and extends to the binding region 22. At least a part of the first connection line 24 is located in the first display sub-region AA1. A width of the first connection line 24 is smaller than a width of the first power signal line 23.

In some embodiments of the present disclosure, the first connection line 24 and the first power signal line 23 may be located in different conductive layers. In this case, the first connection line 24 and the first power signal line 23 need to be connected through a via hole. In some other embodiments of the present disclosure, the first connection line 24 and the first power signal line 23 may be located in a same conductive layer. In this case, the first connection line 24 and the first power signal line 23 can be connected in the conductive layer, without requiring a via hole.

In the display panel shown in FIG. 2, the wire for transmitting the first power signal PVEE includes the first power signal line 23 and the first connection line 24. At least the part of the first connection line 24 are arranged in the first display sub-region AA1, which can save the layout space of the wire for transmitting the first power signal PVEE in the first non-display sub-region BB1, to reduce the width of the first non-display sub-region BB1 and facilitating the narrow frame design.

In some embodiments, two ends of the first power signal line 23 are respectively connected to the binding region 22 through the first connection lines 24 passing through the first display sub-region AA1. In this way, the connection between the first power signal line 23 and the binding region 22 does not occupy a space of the first non-display sub-region BB1, and the width of the first non-display sub-region BB1 can be reduced, especially the width of the R corner region in the lower left corner and the width of the R corner region in the lower right corner in FIG. 2 can be reduced.

In addition, the width of the first connection line 24 is smaller than the width of the first power signal line 23, which can reduce the layout space of the first connection line 24 in the first display sub-region AA1.

The binding region 22 includes pads 221 for fixing the control chip by soldering. The first connection lines 24 are respectively connected to corresponding pads 221, and after the control chip is fixed in the binding region 22 by soldering, the first connection lines 24 can be provided with the first power signal PVEE through the control chip.

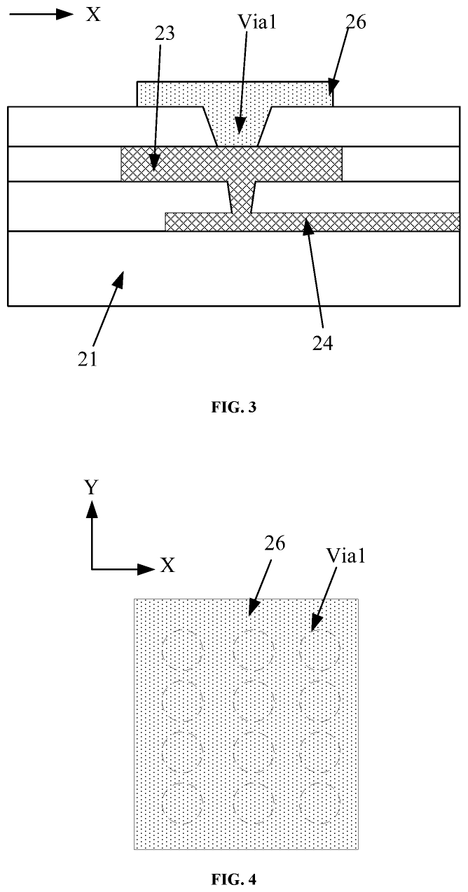

FIG. 3 is a sectional view of a display panel according to an embodiment of the present disclosure. Referring to FIG. 2 and FIG. 3, FIG. 3 is a sectional view of the first power signal line 23 in a second direction X in FIG. 2. The second direction X is perpendicular to the first direction Y, and both directions are parallel to a plane where the substrate 21 is located. The first power signal line 23 includes a first connection portion electrically connected to the first connection line 24. A transfer layer 26 is located on a side of the first power signal line 23 away from the substrate 21. The transfer layer 26 is electrically connected to the first connection portion through a first via hole Via1. The first power signal line 23 includes a first end 231 and a second end 232. One end of the first power signal line 23 may be set as the first connection portion for connecting to the first connection line 24. In one embodiment, both ends of the first power signal line 23 are set as first connection portions. In this case, both ends of the first power signal line 23 are connected with the first connection lines 24.

By designing a parameter of the first via hole Via1, the first via hole Via1 can be used as a protection structure for preventing breakdown at an electrical connection position between the first connection line 24 and the first power signal line 23.

As mentioned above, the width of the first connection line 24 is smaller than the width of the first power signal line 23. Since the widths of the first connection line 24 and the first power signal line 23 are different, there is a sudden change in resistance at the electrical connection position between the first connection line 24 and the first power signal line 23. When there is a static electricity, due to the sudden change of the resistance at the electrical connection position, the static electricity cannot be discharged in time, which can lead to a problem of electrostatic breakdown at the electrical connection position. The first via hole Via1 can be used as a protection structure to prevent the electrostatic breakdown at the electrical connection position between the first connection line 24 and the first power signal line 23.

By designing a parameter of the first via hole Via1, the resistance of the conductive circuit containing the first power signal line 23 can be reduced, to avoid the problem of electrostatic breakdown at the electrical connection position. This is because the current I and time t in the conductive circuit satisfy the following relationship:

$$Q = I * t$$

When an amount of static charge Q is constant, the smaller the resistance of the conductive circuit, the larger the current, and the shorter the time t, and the static electricity can be discharged quickly, avoiding charge accumulation at the electrical connection position between the first connection line 24 and the first power signal line 23, to avoid the electrostatic breakdown at the electrical connection position between the first power signal line 23 and the first connection line 24.

In the embodiment of the present disclosure, a contact area between the first power signal line 23 and the transfer layer 26 can be increased by setting a dimension and/or number of the first via hole Via1, to reduce the resistance of the conductive circuit containing the first power signal line 23.

As mentioned above, the first connection line 24 is electrically connected to the first power signal line 23 at the first connection portion. The first connecting portion is electrically connected to at least one first connection line 24.

One of the first end 231 and the second end 232 may be set as the first connecting portion. In this case, a frame width of an R corner region corresponding to the first connecting portion can be reduced. In one embodiment, both the first end 231 and the second end 232 are set as first connecting portions, to reduce the frame width of the R corner regions corresponding to the two first connecting portions.

In FIG. 2, the first end 231 and the second end 232 are set as first connection portions, as an example for illustration. In this case, the first end 231 and the second end 232 are respectively connected to the corresponding first connection lines 24, which can reduce the frame widths of the two lower R corner regions in FIG. 2. As mentioned above, in some embodiments, only the first end 231 is set as the first connection portion, and the frame width of the lower left R corner region corresponding to the first end 231 can be reduced. In some other embodiments, only the second end 232 is set as the first connection portion, and the frame width of the lower right R corner region corresponding to the second end 232 can be reduced.

In some embodiments, an area ratio of the first via hole Via1 per unit area of the transfer layer 26 is higher than 40%. When the width of the transfer layer 26 in the second direction X is constant, by setting the area ratio of the first via hole Via1 to be higher than 40%, the first power signal line 23 and the transfer layer 26 can have a large contact area to reduce the contact resistance, to reduce the resistance of the conductive circuit containing the first power signal line 23. In some embodiments, the area ratio of the first via hole Via1 per unit area of the transfer layer 26 is in a range from 40% to 70%. In the present disclosure, the number, area, size and shape of a via hole refers to those of a projection of the via hole on the transfer layer.

In some embodiments, the area ratio of the first via hole Via1 per each unit area of the transfer layer 26 can be increased by adjusting the dimension of the first via hole Via1 and/or the number of the first via hole Via1.

Here, the unit area can be set based on requirements, such as 1 mm², or 1 μm², or 1 nm², which is not limited in one embodiment of the present disclosure. For a given unit area, the dimension of the first via hole Via1 is set and the area of the first via hole Via1 is smaller than the unit area and meets the above condition of the area ratio of the first via hole Via1 per each unit area of the transfer layer 26 being in a range from 40% to 70%.

In conventional designs, the area ratio of the first via hole Via1 per each unit area of the transfer layer 26 generally is about 37%. In the embodiment of the present disclosure, the area ratio of the first via hole Via1 is set to be higher than 40%, which leads to a large electrical contact area between the first power signal line 23 and the transfer layer 26, to reduce the contact resistance between the first power signal line 23 and the transfer layer 26, to reduce the resistance of the conductive circuit containing the first power signal line 23, and thus avoid the breakdown at the electrical connection position between the first power signal line 23 and the first connection line 24 when there is the static electricity.

FIG. 4 is a top view of a transfer layer provided by an embodiment of the present disclosure. In one embodiment, first via holes Via1 are provided in a width direction of the transfer layer 26. In this method, the area ratio of the first via holes Via1 per unit area of the transfer layer 26 can be controlled by setting the number of the first via holes Via1, to reduce the contact resistance between the transfer layer 26 and the first power signal line 23. Here, an extension path of the transfer layer 26 is the same as an extension path of the first power signal line 23, both surrounding the second display sub-region AA2. Therefore, the lengths of the transfer layer 26 and the first power signal line 23 are the dimensions along the extension paths, and the widths are the dimensions along a direction parallel to the substrate 21 in a plane perpendicular to the extension path.

FIG. 5 is a top view of a transfer layer according to another embodiment of the present disclosure. In one embodiment, one first via hole Via1 is provided in the width direction of the transfer layer 26. In one embodiment, the area ratio of the first via hole Via1 per unit area of the transfer layer 26 can be controlled by setting the lateral dimension of the first via hole Via1, to reduce the contact resistance between the transfer layer 26 and the first power signal line 23.

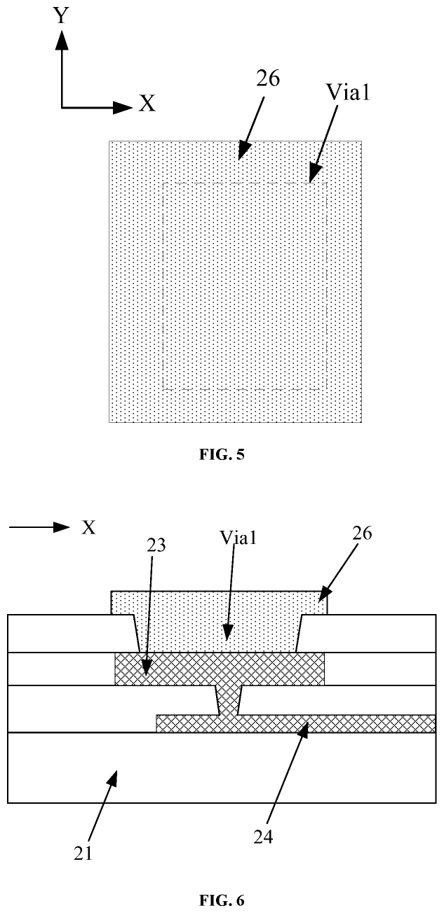

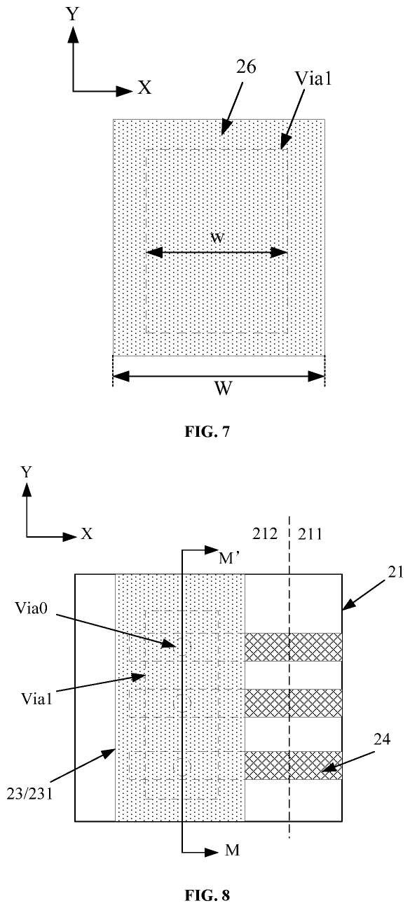

FIG. 6 is a sectional view of another display panel according to an embodiment of the present disclosure. FIG. 7 is a top view of the transfer layer in the display panel shown in FIG. 6. In one embodiment, as shown in FIG. 2, FIG. 6 and FIG. 7, along the width direction of the transfer layer 26, a maximum dimension of the first via hole Via1 is not less than one-third of the width of the transfer layer 26. Denoting the width of the transfer layer 26 as W, in the width direction of the first via hole Via1 (i.e., the second direction X), the maximum dimension of the first via hole Via1 is w≥W/3.

Limited by the current etching process, the first via hole Via1 cannot be formed with a vertical side wall c. As shown in FIG. 6, in a direction from the substrate 21 to the first power signal line 23, the dimension of the first via hole Via1 gradually increases. That is, the dimension at the bottom of the first via hole Via1 is the smallest, and the dimension at the top of the first via hole Via1 is the largest. The dimension at the top is the w. The bottom of the first via hole Via1 is the actual electrical contact area between the transfer layer 26 and the first power signal line 23. For any etching process of the first via Via1, the maximum dimension w at the top of the first via hole Via1 is positively correlated with the minimum dimension at the bottom of the first via hole Via1. Therefore, when w≥W/3, the first via hole Via1 can have a large contact area with the first power signal line 23 and in the width direction of the transfer layer 26, the area ratio of the first via hole Via1 per unit area of the transfer layer 26 higher than 40% can be achieved with a small number of first via holes Via1.

When the width W of the transfer layer 26 is constant, in conventional display panels, along the extension path of the transfer layer 26, generally conductive holes with a maximum dimension smaller than W/3 are arranged on the transfer layer 26 to connect the transfer layer 26 and the first power signal line 23. The conductive holes are arranged sequentially along the extension path of the transfer layer 26, resulting in a small contact area between the first power signal line 23 and the transfer layer 26, and thus a large contact resistance between the first power signal line 23 and the transfer layer 26.

In the embodiment of the present disclosure, setting the dimension w of the first via hole Via1 to be not less than one-third of the width W of the transfer layer 26 can increase the contact area between the transfer layer 26 and the first power signal line 23. In one embodiment, the first via hole Via1 with a large dimension has lower requirements on the drilling process, and the manufacturing process is less difficult than that for the via hole with a small dimension.

When w≥W/3, as shown in FIG. 6 and FIG. 7, along the width direction of the transfer layer 26 (the second direction X), the transfer layer 26 can be connected to the first power signal line 23 through one first via hole Via1. In some other embodiments, the transfer layer 26 can be connected to the first power signal line 23 through two or three first via holes Via1 arranged along the width direction of the transfer layer 26.

The dimension w of the first via hole Via1 is set to be not less than one-third of the width W of the transfer layer 26, and the area ratio of the first via hole Via1 per unit area of the transfer layer 26 can be increased through the first via hole Via1 with a large dimension, to reduce the contact resistance between the transfer layer 26 and the first power signal line 23. In some embodiments, the dimension w of the first via hole Via1 is not less than half of the width W of the transfer layer 26 to increase the contact area between the transfer layer 26 and the first power signal line 23.

A vertical projection of the first via hole Via1 on the plane of the substrate 21 may be in a circular shape, a rectangular shape, a triangular shape, or the like. The embodiment of the present disclosure does not limit the geometric shape of the first via hole Via1.

The transfer layer 26 and the first connection line 24 are different layers. That is, the transfer layer 26 and the first connection line 24 are not the same structure. The electrical contact area between the first power signal line 23 and the transfer layer 26 can be controlled by controlling the number and/or dimension of the first via hole Via1. With the preset number of the first via holes Via1 having the preset dimension, the contact area between the first power signal line 23 and the transition layer 26 is relatively large, to reduce the contact resistance between the first power signal line 23 and the transition layer 26.

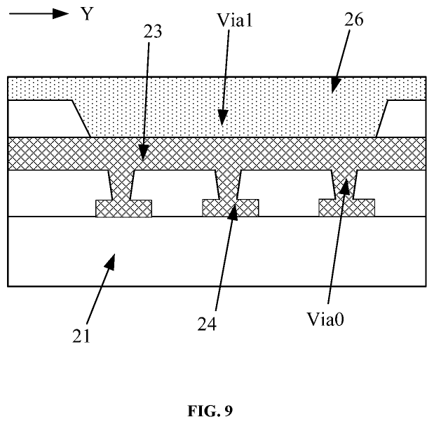

FIG. 8 is a partially enlarged top view of a display panel according to an embodiment of the present disclosure, and FIG. 9 is a sectional view of FIG. 8 in the M-M′ direction. FIG. 8 is a top view of the first connection portion of the first power signal line 23. In FIG. 8, the first end 231 is used as a first connection portion, as an example for illustration. First connection lines 24 are connected to the first connection portion at connection positions Via0 arranged sequentially in the first direction Y. In the direction perpendicular to the plane of the substrate 21, the first via hole Via1 overlaps with the connection positions Via0. That is, the vertical projection of the first via hole Via1 on the substrate 21 covers vertical projections of the connection positions Via0 on the substrate 21.

As shown in FIG. 9, since the width of the first connection line 24 is smaller than the width of the first power signal line 23, there is a sudden change in resistance at the connection position Via0 between the first connection line 24 and the first power signal line 23, which is not conducive to a rapid conduction of static electricity at the connection position. In the embodiment of the present disclosure, the first via hole Via1 is set in the first connection portion corresponding to connection positions Via0, which can greatly reduce the contact resistance between the first power signal line 23 and the transfer layer 26, facilitate the static electricity to quickly pass through connection positions Via0, and avoid the problem of breakdown at the connection position Via0 caused by the accumulation of the static electricity at the connection position Via0.

It should be noted that, in the first direction Y, the first via hole Via1 can be set to correspond to any number of consecutively arranged connection positions Via0, which is not limited to three as shown in FIG. 8 and FIG. 9. In addition, on the extension path of the first power signal line 23, one or more first via holes Via1 can be provided in the first connection portion, which is not limited to one as shown in FIG. 8 and FIG. 9.

In some other embodiments, in a direction perpendicular to the plane where the substrate 21 is located, the first via hole Via1 may overlap at most one connection position Via0. Compared with the manner in which a first via hole Via1 overlaps with connection positions Via0, the manner in which the first via hole Via1 overlaps with at most one connection position Via0 less reduces the resistance of the conductive circuit. However, compared with the layout of conventional conductive holes, the manner in which the first via hole Via1 overlaps with at most one connection position Via0 can also reduce the resistance to some extents.

As shown in FIG. 8 and FIG. 9, the first power signal line 23 and the first connection line 24 are located in different conductive layers, as an example for illustration. Here, the first power signal line 23 and the first connection line 24 need to be connected through a conductive hole, and the connection position Via0 is the position of the conductive hole between the first power signal line 23 and the first connection line 24. As mentioned above, the first power signal line 23 and the first connection line 24 can alternatively be located on the same conductive layer, in which case the connection position is a position where the first power signal line 23 and the first connection line 24 intersect.

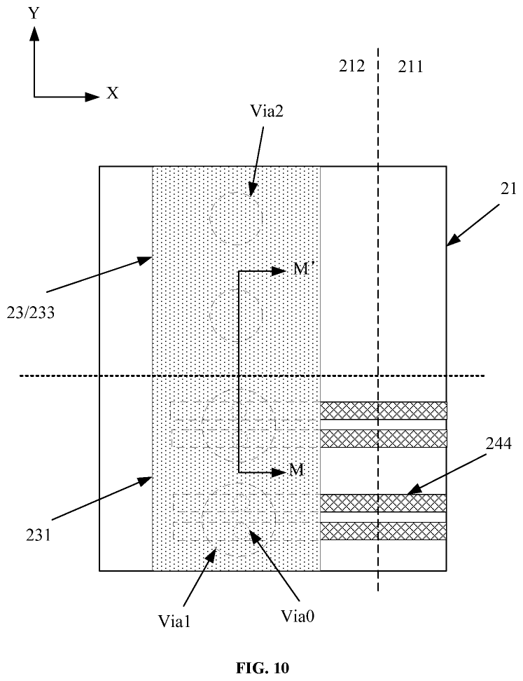

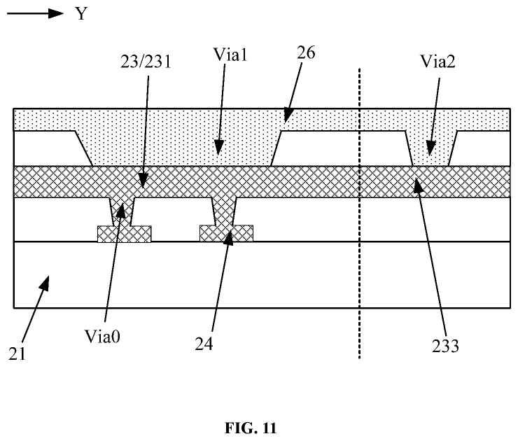

FIG. 10 is a partial enlarged top view of another display panel according to an embodiment of the present disclosure. FIG. 11 is a sectional view of FIG. 10 in the M-M′ direction. FIG. 10 and FIG. 11 show top views of the vicinity of the first end 231 when the first end 231 of the first power signal line 23 is used as the first connection portion. As shown in FIG. 2, FIG. 10 and FIG. 11, the first power signal line 23 includes a second connection portion 233 electrically connected to the transfer layer 26 through a second via hole Via2. Here, the vertical projection of the first via hole Via1 on the substrate 21 has a first area, and the vertical projection of the second via hole Via2 on the substrate 21 has a second area, where the first area is larger than the second area.

As mentioned above, the first power signal line 23 includes a first end 231 and a second end 232. The first end 231 can be served as a first connection portion, and/or the second end 232 can be served as a first connection portion. A part of the first power signal line 23 located between the first end 231 and the second end 232 is a second connection portion 233. The first connection portion is connected to first connection lines 24 arranged in sequence, and a length of the first connection portion in the first power signal line 23 can be determined based on a corresponding area of the connected plurality of first connection lines 24.

In one embodiment of the present disclosure, on the extension path of the transfer layer 26, the first area is set to be larger than the second area, and the electrical contact area of the transfer layer 26 at the first connection portion and the first power signal line 23 is increased, to reduce the contact resistance, compared with the first connection portion and the second connection portion using the conductive holes of the same area to connect to the first power signal line 23. One embodiment can make the first power signal line 23 and the transfer layer 26 have a small contact resistance at the first connection portion, and static electricity can be quickly transferred from the electrical connection position having a sudden change in resistance between the first power signal line 23 and the first connection line 24, to prevent breakdown due to static electricity at the electrical connection position.

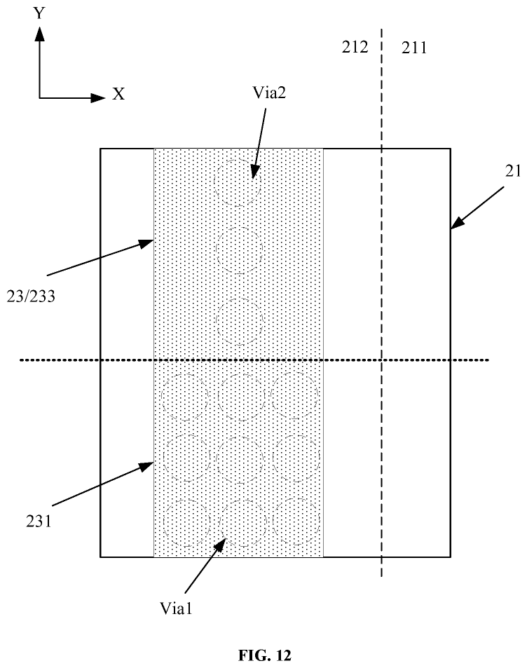

FIG. 12 is a partial enlarged top view of another display panel according to an embodiment of the present disclosure. Referring to FIG. 2, FIG. 3 and FIG. 12, the first power signal line 23 includes a second connection portion 233 electrically connected to the transfer layer 26 through the second via holes Via2. The first via holes Via1 and the second via holes Via2 have the same dimension and the same shape. Along the extension direction of the transfer layer 26, the number of the first via holes Via1 per unit length is greater than the number of the second via holes Via2 per unit length. In one embodiment, the first end 231 is used as an example for illustration. As mentioned above, the second end 232 of the first power signal line 23 can be used as a first connection portion, or both the first end 231 and the second end 232 can be used as first connection portions.

The unit length can be 1 cm, or 1 mm, or 1 μm, which is not limited in the embodiment of the present disclosure. For a given unit length, the dimensions of the first via hole Via1 and the second via hole Via2 are set and the dimension of the first via hole Via1 and the second via hole Via2 is smaller than the unit length, and the number of via holes in the unit length also meets the above-mentioned condition, that is, the first via holes Via1 have the same dimension and the same shape as the second via holes Via2, and the number of the first via hole Via1 per unit length is greater than the number of the second via holes Via2 per unit length along the extension direction of the transfer layer 26.

When the conductive holes connecting the transfer layer 26 to the first power signal line 23 have the same dimension and the same shape, compared with the way that the transfer layer 26 uses the same number of conductive holes per unit length in the extension direction of the transfer layer 26, to electrically connect to the first power signal line 23, the method shown in FIG. 12 can increase the electrical contact area between the transfer layer 26 and the first power signal line 23, to reduce the contact resistance. In particular, compared with the second connecting portion 232, the first connection portion uses a larger number of first via holes Via1 per unit length to connect to the first power signal line 23, which can lead to a small contact resistance between the first power signal line 23 and the transfer layer 26 in an area close to the electrical connection position between the first power signal line 23 and the first connection line 24, and the static electricity can be quickly transferred from the electrical connection position having a sudden change in resistance between the first power signal line 23 and the first connection line 24, to avoid the breakdown at the electrical connection position due to the static electricity.

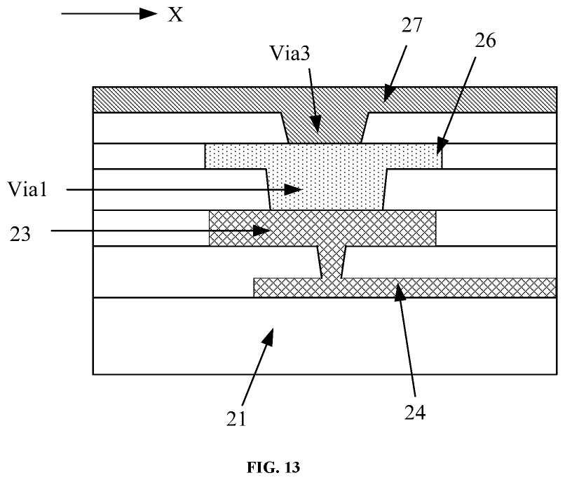

FIG. 13 is a sectional view of another display panel according to an embodiment of the present disclosure. A cathode layer 27 is provided on a side of the transfer layer 26 away from the substrate 21. The cathode layer 27 is electrically connected to the transfer layer 26 through a third via hole Via3. In a part of the non-display region 212 where the cathode layer 27 is located, the area ratio of the third via hole Via3 per unit area is higher than 40%, and the area of electrical connection between the transfer layer 26 and the cathode layer 27 is large, which can reduce the resistance of the conductive circuit containing the first power signal line 23.

The transfer layer 26 is located between the cathode layer 27 and the first power signal line 23.

The third via hole Via3 can be used as a protection structure. By setting the large area ratio of the third via hole Via3 per unit area, the resistance of the conductive circuit containing the first power signal line 23 is small, to avoid the accumulation of static electricity at the connection position between the first power signal line 23 and the first connection line 24.

In one embodiment, the area ratio of the third via hole Via3 is 40% to 70% per unit area. By setting the area ratio of the third via hole Via3 per unit area to be in a range from 40% to 70%, a large contact area between the transfer layer 26 and the cathode layer 27 is achieved within an allowable range of process accuracy, which reduces the contact resistance between the transfer layer 26 and the cathode layer 27, to achieve small resistance of the conductive circuit containing the first power signal line 23.

In some embodiments, the cathode layer 27 is a layer of transparent electrodes. The cathode layer 27 includes a first part located in the display region 211 and a second part located in the non-display region 212. The first part of the cathode layer and the second part of the cathode layer are integrated as a whole. The cathode layer 27 is connected to the transfer layer 26 through the third via hole Via3, and thus is connected to the first power signal line 23, and the cathode layer 27 can receive the first power signal PVEE.

As mentioned above, the cathode layer 27 includes a first part located in the display region 211 and a second part located in the non-display region 212. The first part of the cathode layer and the second part of the cathode layer are integrated. The second part of the cathode layer is connected to the transfer layer 26 through the third via holes Via3. As shown in FIG. 13, along the direction perpendicular to the substrate 21, in the second part of the cathode layer, the projection of the third via hole Via3 at least partially overlaps the projection of the first via hole Via1, to reduce the contact resistance between the cathode layer 27 and the transfer layer 26, to reduce the resistance of the conductive circuit containing the first power signal line 23, avoiding accumulation of static electricity at the connection position between the first power signal line 23 and the first connection line 24, and thus avoiding the breakdown at the connection position.

In some embodiments, along the direction perpendicular to the substrate 21, in the second part of the cathode layer, the projection of the third via hole Via3 at least partially overlaps the projection of the second via hole Via2, to further reduce the contact resistance between the cathode layer 27 and the transfer layer 26.

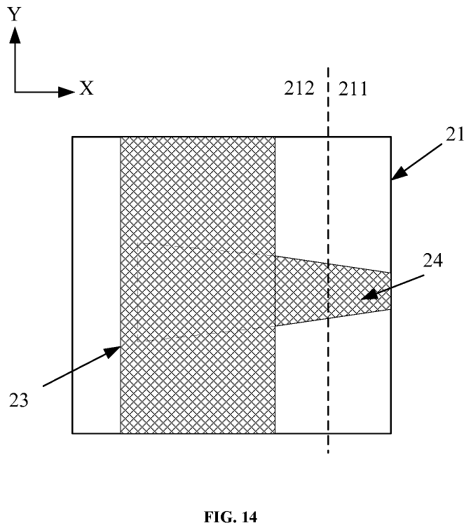

FIG. 14 is a partial enlarged top view of another display panel according to an embodiment of the present disclosure. Along a direction from the first connection line 24 to the first power signal line 23 (the opposite direction of the second direction X shown in FIG. 14), the width of the first connection line 24 is gradually increased, and the first connection line 24 has a largest line width at the connection position with the first power signal line 23, and the first connection line 24 and the first power signal line 23 have a large electrical contact area at this connection position and have a low contact resistance. It should be noted that, for ease of illustration, FIG. 14 shows only the substrate 21, the first connection line 24 and the first power signal wire body 23.

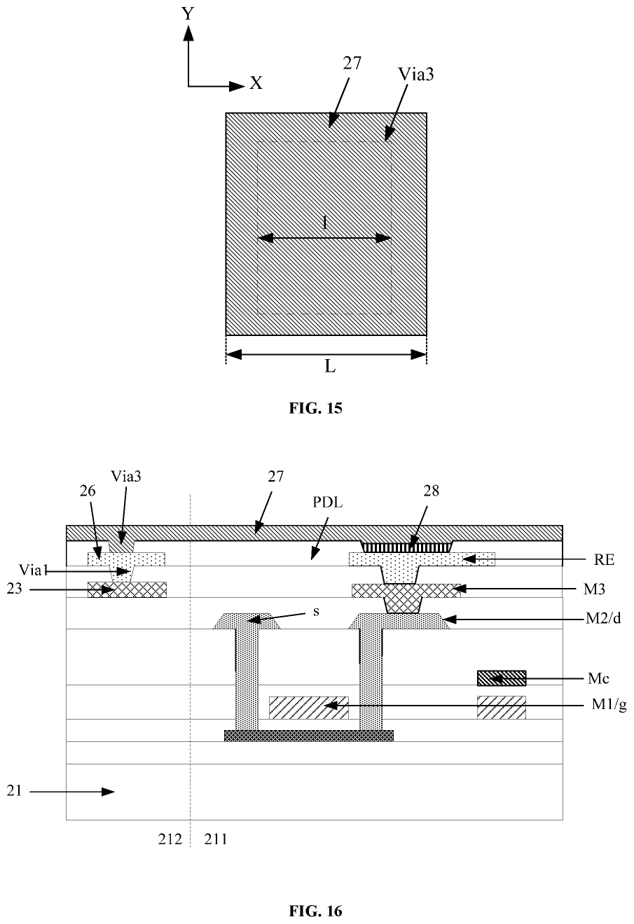

FIG. 15 is a top view of a cathode layer in a non-display region according to an embodiment of the present disclosure. Referring to FIG. 13 and FIG. 15, the cathode layer 27 and the transfer layer 26 are connected to each other through the third conductive hole Via3. The dimension l of the third conductive hole Via3 is greater than one-third of the width L of the second part of the cathode layer. This design can form a third conductive hole Via3 with a large dimension in the second part of the cathode layer, and the transfer layer 26 and the cathode layer 27 have a large contact area and the contact resistance between the transfer layer 26 and the cathode layer 27 can be reduced.

In some embodiments, the dimension l of the third conductive hole Via3 is larger than half of the width L of the second part of the cathode layer.

In some embodiments of the present disclosure, the display panel may be an OLED display panel. When an OLED display panel is used, a sectional view of the display panel in the display region 211 can be as shown in FIG. 16.

FIG. 16 is a sectional view of another display panel according to an embodiment of the present disclosure. A thin film transistor (TFT) array is arranged on the surface of the substrate 21 to form a pixel circuit to drive light emitting elements to perform light emitting display. All the thin film transistors and the light emitting elements are located in the display region 211.

The thin film transistor includes a gate electrode g on the first metal layer M1, a source electrode s and a drain electrode d on the second metal layer M2. The first metal layer M1 is located between the second metal layer M2 and the substrate 21.

The light emitting element is located on a side of the thin film transistor array away from the substrate 21. In a direction from the substrate 21 to the light emitting element, the light emitting element includes an anode RE, an organic light emitting layer 28 and a cathode layer 27 stacked in sequence. A pixel definition layer PDL is disposed above the anode RE and includes a pixel opening to expose a part of the anode RE. The organic light emitting layer 28 of the light emitting element is located in the pixel opening. All the light emitting elements have a common cathode layer 27.

The cathode layer 27 extends from the display region 211 to the non-display region 212, and the part in the non-display region 212 is used to realize the connection with the first power signal line 23 to receive the first power signal PVEE. As mentioned above, the cathode layer 27 can be connected to the transfer layer 26 through the third via hole Via3, and the transfer layer 26 is connected to the first power signal line 23 through the first via hole Via1, to realize the connection between the part of the cathode layer 27 in the non-display region 212 and the first power signal line 23.

A third metal layer M3 is located between the anode RE and the second metal layer M2. The anode RE is connected to the drain electrode d of the thin film transistor through the third metal layer M3. A fourth metal layer Mc is located between the first metal layer M1 and the second metal layer M2, and is used for producing a storage capacitor of the pixel circuit. There is an insulating layer between different metal layers.

As shown in FIG. 16, the first power signal line 23 is located on the third metal layer M3. The transfer layer 26 is located on the same conductive layer as the anode RE.

In some embodiment of the present disclosure, in the non-display region 212, the second metal layer M2 or the third metal layer M3 can be reused to produce the first power signal line 23, which is not limited in the embodiment of the present disclosure.

When the second metal layer M2 is reused to produce the first power signal line 2, the transfer layer 26 includes the metal layer where the anode RE is located and the third metal layer M3. The transfer layer 26 is disconnected from a same conductive layer in the display region 211.

As shown in FIG. 2 and FIG. 16, in the first display sub-region AA1, the first connection line 24 needs to be insulated and intersected with signal lines (such as data lines and second power signal lines) extending along the first direction Y in the display region 211. To achieve the insulation and intersection, one or more of the first metal layer M1 to the fourth metal layer Mc in the display region 211 can be reused to produce the first connection line 24. If there is a line intersects the first connection line 24 on the same layer, the first connection line 24 can be changed to another layer selected from one or more of the first metal layer M1 to the fourth metal layer Mc.

In some embodiments, in order to simplify the wiring of the first electrical connection line 24 and avoid holes required for making a line across different metal layers, a fifth metal layer is added on the substrate 21. The fifth metal layer is located between the thin film transistor array and the substrate 21. Through the added fifth metal layer, the first electrical connection line 24 will not be short-circuited with another line intersected in the same metal layer in the display panel, which facilitates the wiring of the first connection line 24.

In the above embodiments, by setting the layout scheme of the first via hole Via1, the resistance of the conductive circuit containing the first power signal line 23 is reduced, and the static electricity is transferred rapidly from the electrical connection position between the first power signal line 23 and the first connection line 24, to avoid the problem of breakdown at the electrical connection position due to static electricity. The first power signal line 23 can discharge static electricity to the ground through the transfer layer 26 that is electrically connected to the first power signal line 23, or discharge the static electricity to the ground through the transfer layer 26 and the cathode layer 27 sequentially.

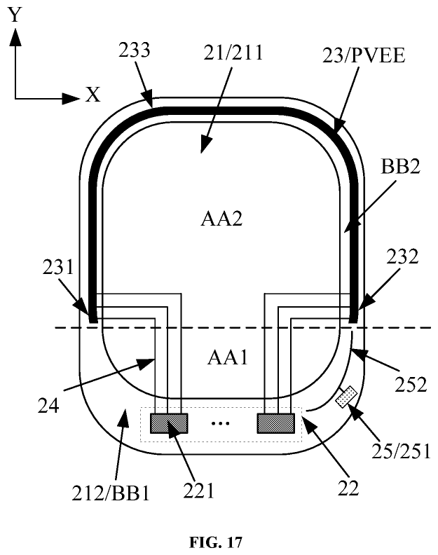

FIG. 17 is a structural schematic diagram of another display panel according to an embodiment of the present disclosure. On the basis of the design shown in FIG. 2, in the design shown in FIG. 17, the display panel includes an electrostatic protection structure 25 located in the first non-display sub-region BB1. The electrostatic protection structure 25 is configured to transmit and absorb electrostatic charges, to avoid accumulation of static electricity at the electrical connection position between the first power signal line 23 and the first connection line 24, to avoid the problem of electrostatic breakdown at the electrical connection position.

As shown in FIG. 17, the electrostatic protection structure 25 includes an electrostatic transmission line 252 and an electrostatic discharge circuit 251, the electrostatic transmission line 252 is connected to the electrostatic discharge circuit 251, and the electrostatic transmission line 252 is configured to transfer static electricity to the electrostatic discharge circuit 251, to discharge static electricity through the electrostatic discharge circuit 251.

Since the first non-display region BB1 is not surrounded by the wire for transmitting the first power signal PVEE, the first non-display region BB1 lacks the electrostatic protection function of the first power signal line 23, which results in a weak anti-static capability in this area. By setting the electrostatic protection structure 25 located in the first non-display sub-region BB1, it is possible to avoid an electrostatic protection blind area in the first non-display region BB1.

The first power signal line 23 includes a first end 231 and a second end 232. The binding region 22 includes a first pad (the pad 221 at the left end in FIG. 17) and a second pad (the pad 221 at the right end in FIG. 17). The first end 231 is electrically connected to the first pad through the corresponding first connection lines 24, and the second end 232 is electrically connected to the second pad through the corresponding first connection lines 24. In some embodiments, in the first non-display region BB1, two electrostatic protection structures 25 are respectively located between the first end 231 and the first pad, and between the second end 232 and the second pad. For example, the two electrostatic protection structures 25 are respectively arranged at the lower left R corner region and the lower right R corner region of the display panel. In this way, the first non-display region BB1 has a good electrostatic protection. In some other ways, in the first non-display region BB1, an electrostatic protection structure 25 is provided between the first end 231 and the first pad, or between the second end 232 and the second pad. FIG. 17 only illustrates the electrostatic protection structure 25 disposed between the second end 232 and the second pad as an example.

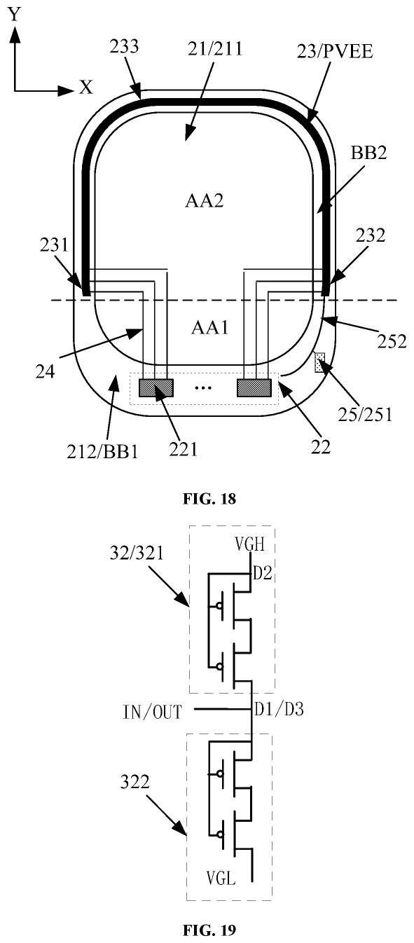

FIG. 18 is a structural schematic diagram of another display panel according to an embodiment of the present disclosure. In one embodiment, an electrostatic transmission line 252 is connected to the first power signal line 23, and the static electricity in the conductive circuit containing the first power signal line 23 can be discharged through the electrostatic protection structure 25. Therefore, the transmission path of the static electricity in the conductive circuit containing the first power signal line 23 is shortened, to quickly discharge the static electricity, preventing the static electricity from accumulating at the connection position between the first power signal line 23 and the first connection line 24.

In some other ways, the electrostatic protection structure 25 is disconnected from the first power signal line 23. In this case, the electrostatic protection structure 25 can absorb and discharge the static electricity in the first display sub-region BB1, preventing this part of static electricity from entering the conductive circuit containing the first power signal line 23, and thus reducing the accumulation of static electricity at the connection position between the first power signal line 23 and the first connection line 24.

An electrostatic discharge circuit 32 may be provided to quickly absorb/discharge static electricity, to prevent damage at the R corner region due to accumulation of static electricity in the R corner region.

As shown in FIG. 18, the electrostatic transmission line 252 is connected to the first power signal line 23, to form a closed electrostatic protection structure for the region between the end of the first power signal line 23 and the binding region 22, improving the electrostatic protection effect of the first non-display region BB1. In addition, the absorption/discharge of static electricity can be accelerated by the electrostatic discharge circuit 251.

In some embodiments, as shown in FIG. 17 and FIG. 18, in order to reduce the frame width of the first non-display region 211 at the R corner region, the width of the electrostatic transmission line 252 is set to be smaller than the width of the first power signal line 23. Compared with the manner shown in FIG. 1, in the display panels shown in FIG. 17 and FIG. 18, since the width of the electrostatic transmission line 252 is smaller than the width of the first power signal line 23, the frame width of the first non-display region 211 at the R corner region can be reduced.

FIG. 19 is a schematic structural diagram of an electrostatic discharge circuit according to an embodiment of the present disclosure. Referring to FIG. 18 and FIG. 19, the electrostatic discharge circuit 251 includes a first electrostatic discharge branch 321 and a second electrostatic discharge branch 322. The first electrostatic discharge branch 321 includes a first port D1 and a second port D2. The first port D1 is connected to the electrostatic transmission line 252, and the second port D2 is connected to a first voltage VGH. The second electrostatic discharge branch 322 includes a third port D3 and a fourth port D4. The third port D3 is connected to the electrostatic transmission line 252, and the fourth port D4 is connected to a second voltage VGL. Here, the first voltage VGH is greater than the second voltage VGL. When a voltage of the electrostatic transmission line 252 is greater than the first voltage VGH, the first electrostatic discharge branch 321 is turned on to discharge static electricity. When the voltage of the electrostatic transmission line 252 is lower than the second voltage VGL, the second electrostatic discharge branch 322 is turned on to discharge static electricity. As shown in FIG. 19, the electrostatic discharge circuit 32 can realize the absorption/discharge of static electricity based on two electrostatic discharge circuits, having a simple circuit structure.

As shown in FIG. 19, each of the first electrostatic discharge branch 321 and the second electrostatic discharge branch 322 include two PMOSs. The display region 211 includes thin film transistors for controlling the light emitting elements to display images. The PMOSs of the electrostatic discharge branches in the non-display region 212 can be produced in the same process as producing the thin film transistors in the display region 211. An active region of the PMOS in the electrostatic discharge circuit 251 and an active region of the thin film transistor in the display region 211 are located in a same semiconductor layer and can be produced at the same time. A gate electrode of the PMOS in the electrostatic discharge circuit 251 and a gate electrode of the thin film transistor in the display region 211 are located on the first metal layer and can be produced at the same time. A source electrode and a drain electrode of the PMOS in the electrostatic discharge circuit 251 and a source electrode and a drain electrode of the thin film transistor in the display region 211 are located on the second metal layer and can be produced at the same time.

Therefore, the display panel shown in FIG. 19 does not require additional process steps to produce the electrostatic discharge circuit 32, which is simple and compatible with the existing manufacturing process of the display panel.

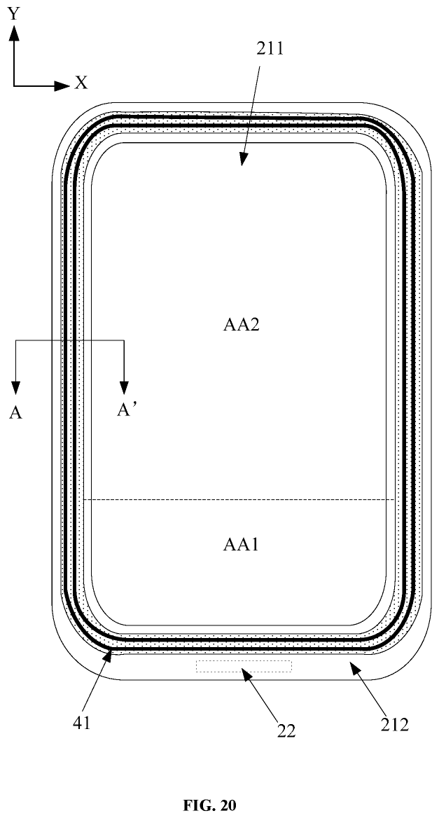

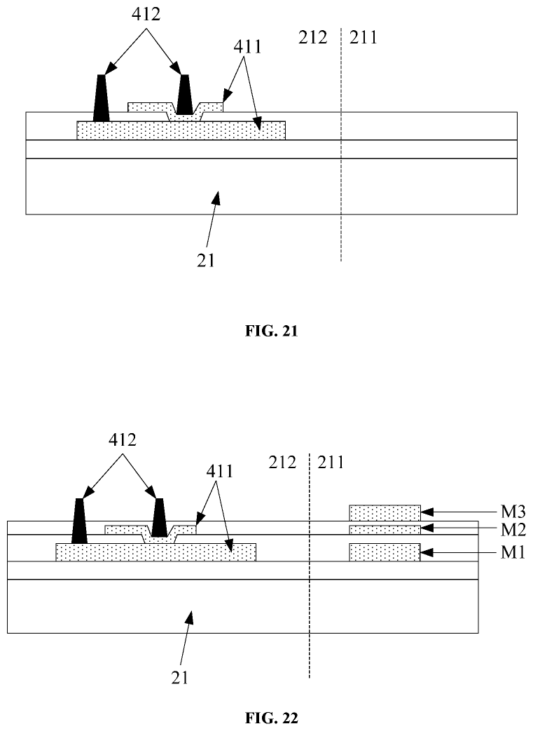

FIG. 20 is a schematic structural diagram of another display panel according to an embodiment of the present disclosure. FIG. 21 is a sectional view of the display panel shown in FIG. 20 at the line A-A′. For ease of illustration, the above-mentioned first power signal line 23 and electrostatic protection structure 25 located in the non-display region 212, the first connection line 24 located in the display region 211, the light emitting element and the thin film transistor structure are not shown in FIGS. 20 and 21.

As shown in FIG. 18, FIG. 20 and FIG. 21, the non-display region 212 includes a retaining wall 41 surrounding the display region 211, and the retaining wall 41 includes metal layers 411 and non-metallic layers 412 stacked. The electrostatic transmission line 252 is provided in at least one metal layer 411 of the retaining wall 41. In this way, the metal layer 411 of the retaining wall 41 in the display panel is reused to produce the electrostatic transmission line 252, without requiring a separate metal to produce the electrostatic transmission line 252. Therefore, the thickness of the display panel is not reduced, the manufacturing method is simple and the manufacturing cost is low. The retaining wall 41 surrounds the first power signal line 23. That is, the first power signal line 23 is located in the area surrounded by the retaining wall 41.

As shown in FIG. 20 and FIG. 21, the display panel is a flexible display panel. In order to make the display panel highly flexible, the display panel includes layers of organic materials with good flexibility. In order to prevent water vapor from invading the display region 211 through the organic materials, the flexible display panel is provided with the retaining wall 41 around the display region 211. In the embodiment of the present disclosure, the metal layer 41 of the retaining wall 41 is reused to produce the electrostatic transmission line 252, which has good compatibility with the manufacturing process of the flexible display panel without additional process steps. The electrostatic discharge circuit 251 can be used to quickly absorb/discharge static electricity, to avoid package failure caused by electrostatic breakdown in the R corner region caused by static electricity.

FIG. 22 is a sectional view of a display panel according to an embodiment of the present disclosure in a direction perpendicular to an extending direction of the retaining wall. For ease of illustration, the above-mentioned first power signal line 23 and the electrostatic discharge circuit 32 located in the non-display region 212, the first connection line 24 located in the display region 211, the light emitting element and the thin film transistor structure are not shown in FIG. 22. As shown in FIGS. 18 and 20-22, a first metal layer M1, a second metal layer M2, and a third metal layer M3 are sequentially arranged on the substrate 21, and there is an insulating layer between adjacent metal layers. The electrostatic transmission line 252 is located in at least one of the first metal layer M1, the second metal layer M2, and the third metal layer M3.

FIG. 22 shows an example that the retaining wall 41 includes a part of the first metal layer M1 located in the non-display region 212 and a part of the second metal layer M2 located in the non-display region 212. In this case, the electrostatic transmission line 252 can be produced by reusing the first metal layer M1 and/or the second metal layer M2.

As mentioned above, the display panel includes metal layers. The manner shown in FIG. 22 reuses at least one of the first metal layer M1, the second metal layer M2, and the third metal layer M3 to produce the electrostatic transmission line 252, leading to a small thickness of the display panel, a simple manufacturing process and a low manufacturing cost.

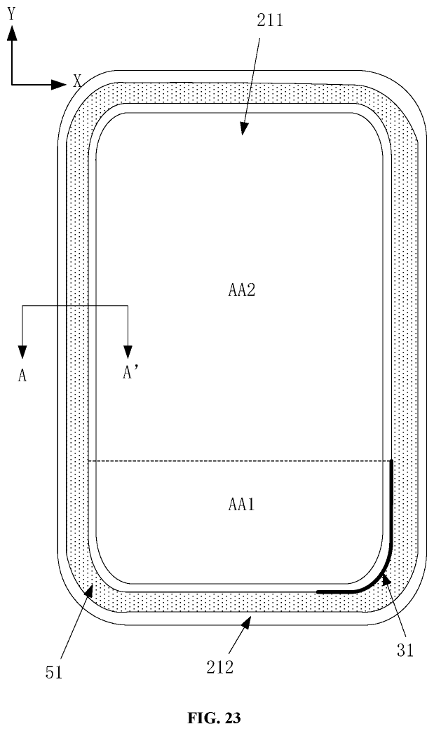

FIG. 23 is a schematic structural diagram of another display panel according to an embodiment of the present disclosure. In one embodiment, the non-display region 212 includes a metal case 51 surrounding the display region 211, and the metal case 51 is reused as the electrostatic transmission line 252. As shown in FIG. 18 and FIG. 23, the metal case 51 surrounds the first power signal line 23. That is, the first power signal line 23 is located in an area surrounded by the metal case 51. For clear illustration, the first power signal line 23, the binding region 22 and the first connection line 24 are not shown in FIG. 23. In this way, the metal case 51 in the display panel is reused to produce the electrostatic transmission line 252, without requiring a separate film layer. Therefore, the thickness of the display panel is reduced, the manufacturing process is simple and the manufacturing cost is low.

The display panel shown in FIG. 23 is a rigid display panel with the metal case 51, where the metal case 51 in the rigid display panel can be reused to produce the electrostatic transmission line 252.

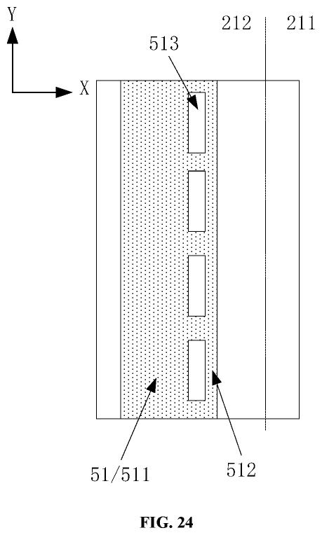

FIG. 24 is a partially enlarged view of a display panel according to an embodiment of the present disclosure. As shown in FIG. 18, FIG. 23 and FIG. 24, the metal case 51 includes a hollow part 513. At least a part of the hollow part 513 is located in the first non-display sub-region BB1. The metal case 51 includes a first portion 512 and a second portion 511. The first portion 512 is located between the hollow part 513 and the display region 211, and the second portion 511 is located on a side of the hollow part 513 away from the display region 211. The width of the first portion 512 is smaller than that of the second portion 511, and the electrostatic discharge circuit 251 is electrically connected to the first portion 512. In this way, the metal case 51 is divided into two parts by the hollow part 513, and the first area 512 can be reused as the electrostatic transmission line 252.

In some embodiments, the first portion 512 is connected to the electrostatic discharge circuit 251 through a wire in the first metal layer M1 or the second metal layer M2.

The hollow part 513 is provided in a preset area of the metal case 51, and the preset area is an area having weak electrostatic protection, and can quickly conduct static electricity to the metal case 51 near the hollow part 513, to avoid the accumulation of static electricity at the electrical connection position between the first power signal line 23 and the first connection line 24. The static electricity conducted to the metal case 51 can be absorbed during the transmission of the conductive circuit, and can also be absorbed/discharged by the electrostatic discharge circuit 251.

In some embodiments, as shown in FIG. 24, the width of the second portion 511 is greater than the width of the first portion 512. In this way, when the static electricity is transmitted in the first portion 512 with a narrow width, the static electricity can be consumed and absorbed quickly.

In the embodiment of the present disclosure, the ratio of the width of the hollow part 513 to the width of the metal case 51 is in a range from 3% to 10%. Within the range of the width ratio, fast absorption/discharge of static electricity can be achieved.

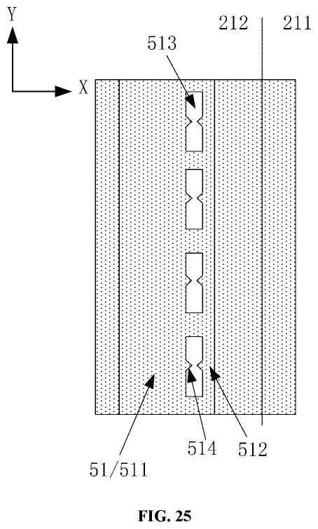

Referring to FIG. 25, FIG. 25 is a partial enlarged view of another display panel according to an embodiment of the present disclosure. Based on the structure shown in FIG. 24, in the electronic device shown in FIG. 25, the hollow part 513 includes a tip structure 514 protruding toward the inside of the hollow part 513. By the tip discharge phenomenon of the tip structure 514, the absorption/discharge of static electricity can be fast. The tip structure 514 may be a triangular sawtooth, a rectangular sawtooth with sharp corners, a polygonal sawtooth, etc., which is not limited in this embodiment of the present disclosure.

It should be noted that any of the embodiments shown in FIGS. 2 to 16 can be combined with any of the embodiments shown in FIGS. 17 to 25. That is, for a display panel provided with the first power signal line 23 and the first connection line 24, the display panel can further include the first via hole Via1 and the electrostatic protection structure 25, or the display panel can also include the first via hole Via1, the second via hole Via2, and the electrostatic protection structure 25, or the display panel can also include the first via hole Via1 and the second via hole Via2, the third via hole Via3 and the electrostatic protection structure 25.

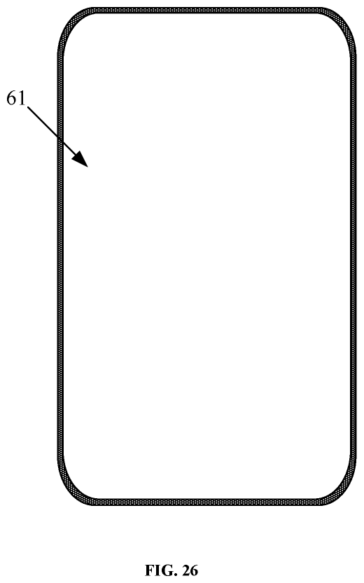

Based on the above embodiments, another embodiment of the present disclosure further provides an electronic device, as shown in FIG. 26. The electronic device includes a display panel 61.

The display panel 61 is the display panel described in any one of the above embodiments, so the electronic device can realize a narrow frame design.

The electronic device may be a mobile phone, a tablet computer, a vehicle-mounted display device, a wearable device or other device with a display function.

Each embodiment in the present disclosure is described in a progressive manner, a parallel manner, or a progressive and parallel manner. Each embodiment focuses on the differences from other embodiments. The same and similar parts between the various embodiments can be referred to each other. As for the electronic device, since it corresponds to the display panel, the description is relatively simple. For the relevant information, one may refer to the relevant part of the description of the display panel.

It should be noted that in the description of the present application, the descriptions of the drawings and embodiments are illustrative rather than restrictive. Like reference numerals identify like structures throughout the embodiments of the specification. In addition, for the sake of understanding and ease of description, the thickness of some layers, films, panels, regions, etc. may be exaggerated in the drawings. Also, it will be understood that when an element such as a layer, film, region, or substrate is referred to as being “on” another element, it can be directly on the other element or intermediate elements may be present. In addition, “on” means positioning an element on or under another element, but does not essentially mean positioning on an upper side of another element according to the direction of gravity.

The orientation or positional relationship indicated by the terms “upper”, “lower”, “top”, “bottom”, “inner”, “outer” and so on are based on the orientation or positional relationship shown in the drawings, and are only for the convenience of describing the present application and simplified descriptions, rather than indicating or implying that the device or element referred to must have a specific orientation, be constructed and operate in a specific orientation, and thus should not be construed as limiting the application. When a component is described to be “connected” to another component, it may be directly connected to the other component or connected through another component.

It should also be noted that in this article, relational terms such as first and second etc. are only used to distinguish one entity or operation from another entity or operation, and do not necessarily require or imply that these entities or operations have any such actual relationship or sequence. Moreover, the term “comprises”, “include” or any other variation thereof is intended to cover a non-exclusive inclusion and an article or device including a set of elements includes not only those elements but also other elements not expressly listed, or also include elements inherent to the article or device. Without further limitations, an element defined by the phrase “comprising a . . . ” does not exclude the presence of additional identical elements in an article or device including the aforementioned element.

The above description of the disclosed embodiments is provided to enable the making or using of the present application. Various modifications to these examples will be readily apparent, and the general principles defined herein may be implemented in other embodiments without departing from the spirit or scope of the application. Therefore, the present application will not be limited to the embodiments shown herein, but is to be accorded the widest scope consistent with the principles and novel features disclosed herein.

What is claimed is:

1. A display panel, comprising:
a substrate, comprising:
a display region and a non-display region surrounding the display region, wherein the display region comprises a first display sub-region and a second display sub-region arranged in sequence in a first direction, the non-display region comprises a first non-display sub-region arranged along a periphery of the first display sub-region and a second non-display sub-region arranged along a periphery of the second display sub-region, the first non-display sub-region comprises a binding region, and the binding region is opposite to the first display sub-region in the first direction;
a first power signal line, located in the second non-display sub-region; and
a first connection line, electrically connected to a part of the first power signal line, and extending to the binding region, and at least partially located in the first display sub-region, wherein a width of the first connection line is smaller than a width of the first power signal line.

2. The display panel according to claim 1, wherein the first power signal line comprises a first connection portion electrically connected to the first connection line, and a transfer layer is provided on a side of the first power signal line away from the substrate, the transfer layer is electrically connected to the first connection portion through a first via hole.

3. The display panel according to claim 2, wherein an area ratio of a projection of the first via hole on the transfer layer per unit area of the transfer layer is higher than 40%.

4. The display panel according to claim 2, wherein, in a width direction of the transfer layer, a maximum dimension of the first via hole is not less than one-third of a width of the transfer layer.

5. The display panel according to claim 2, wherein the first connection portion is connected to a plurality of the first connection lines at a plurality of connection positions arranged sequentially in the first direction;
in a direction perpendicular to a plane where the substrate is located, the first via hole overlaps with the plurality of the connection positions.

6. The display panel according to claim 2, wherein the first power signal line comprises a second connection portion electrically connected to the transfer layer through a second via hole;
a vertical projection of the first via hole on the substrate has a first area, a vertical projection of the second via hole on the substrate has a second area, and the first area is larger than the second area.

7. The display panel according to claim 2, wherein the first power signal line comprises a second connection portion electrically connected to the transfer layer through a plurality of second via holes;
the first via hole comprises a plurality of first via holes having the same shape and same dimension as the second via holes, and along an extension direction of the transfer layer, a number of projections of the first via holes on the transfer layer per unit length of the transfer layer is greater than a number of projections of the second via holes on the transfer layer per unit length of the transfer layer.

8. The display panel according to claim 2, wherein a cathode layer is provided on a side of the transfer layer away from the substrate, the cathode layer is electrically connected to the transfer layer through a third via hole;
in a part of the cathode layer in the non-display region, an area ratio of a projection of the third via hole on the transfer layer per unit area of the transfer layer is higher than 40%.

9. The display panel according to claim 2, wherein a cathode layer comprises a first part located in the display region and a second part located in the non-display region, the first part of the cathode layer and the second part of the cathode layer are integrated as a whole, the second part of the cathode layer is connected to the transfer layer through a third via hole;
along the direction perpendicular to the substrate, a projection of the third via hole on the second part of the cathode layer at least partially overlaps a projection of the first via hole.

10. The display panel according to claim 1, wherein along a direction from the first connection line to the first power signal line, the width of the first connection line is gradually increased.

11. The display panel according to claim 1, wherein the display panel comprises an electrostatic protection structure located in the first non-display sub-region, and the electrostatic protection structure comprises an electrostatic transmission line and an electrostatic discharge circuit, the electrostatic transmission line is electrically connected to the electrostatic discharge circuit, and the electrostatic transmission line is configured to transmit static electricity to the electrostatic discharge circuit.

12. The display panel according to claim 11, wherein the electrostatic transmission line is connected to the first power signal line.

13. The display panel according to claim 11, wherein the electrostatic discharge circuit comprises:
a first electrostatic discharge branch, wherein the first electrostatic discharge branch comprises a first port and a second port, the first port is connected to the electrostatic transmission line, and the second port is connected to a first voltage; and
a second electrostatic discharge branch, the second electrostatic discharge branch comprises a third port and a fourth port, the third port is connected to the electrostatic transmission line, and the fourth port is connected to a second voltage;
wherein the first voltage is greater than the second voltage, when a voltage of the electrostatic transmission line is greater than the first voltage, the first electrostatic discharge branch is turned on to discharge static electricity, when the voltage of the electrostatic transmission line is lower than the second voltage, the second static electricity discharge branch is turned on to discharge static electricity.

14. The display panel according to claim 11, wherein a line width of the electrostatic transmission line is smaller than a line width of the first power signal line.

15. The display panel according to claim 11, wherein a retaining wall is provided in the non-display region, and the retaining wall comprises metal layers and non-metal layers stacked, and the electrostatic transmission line is provided in at least one of the metal layers of the retaining wall.

16. The display panel according to claim 15, wherein a first metal layer, a second metal layer and a third metal layer are sequentially arranged on the substrate, and there is an insulating layer between adjacent metal layers; the electrostatic transmission line is located in at least one of the first metal layer, the second metal layer and the third metal layer.

17. The display panel according to claim 11, wherein the non-display region comprises a metal case surrounding the display region, and the metal case is reused as the electrostatic transmission line.

18. The display panel according to claim 17, wherein the metal case comprises a hollow part, at least a part of the hollow part is located in the first non-display sub-region, the metal case comprises a first portion and a second portion, the first portion is located between the hollow part and the display region, the second portion is located on a side of the hollow part away from the display region, a width of the first portion is smaller than a width of the second portion, and the electrostatic discharge circuit is electrically connected to the first portion.

19. The display panel according to claim 18, wherein a ratio of a width of the hollow part to a width of the metal case is in a range from 3% to 10%.

20. An electronic device, comprising:
a display panel, wherein the display panel comprises:
a substrate, comprising a display region and a non-display region surrounding the display region, wherein the display region comprises a first display sub-region and a second display sub-region arranged in sequence in a first direction, the non-display region comprises a first non-display sub-region arranged along a periphery of the first display sub-region and a second non-display sub-region arranged along a periphery of the second display sub-region, the first non-display sub-region comprises a binding region, and the binding region is opposite to the first display sub-region in the first direction;
a first power signal line, located in the second non-display sub-region; and
a first connection line, electrically connected to a part of the first power signal line, and extending to the binding region, and at least partially located in the first display sub-region, wherein a width of the first connection line is smaller than a width of the first power signal line.
